(19) United States
(12) Patent Application Publication
(10) Pub. No.: US 2005/0156635 A1
(43) Pub. Date: Jul. 21, 2005

(54) Light-emitting element driver circuit

(75) Inventors: Teru Yoneyama, Kanagawa (JP); Yutaka Saeki, Kanagawa (JP)

Correspondence Address: MCGINN & GIBB, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 11/028,672

(22) Filed: Jan. 5, 2005

(30) Foreign Application Priority Data
Jan. 21, 2004 (JP) 2004-013465

(51) Int. Cl. H03B 1/00

(52) U.S. Cl. 327/108

(57) ABSTRACT

Disclosed is a display driver that includes a first current driver circuit, which has a plurality of current sources for outputting current of a value decided based upon a reference current, and switch circuits that on/off control current paths between the plurality of current sources and a current output terminal based upon a prescribed lower-order bit signal of a video signal, for outputting a first output current conforming to the prescribed lower-order bit signal of the video signal; a second current driver circuit for outputting a second output current conforming to a higher-order bit signal of the video signal; and a current-source circuit for varying the reference current based upon the higher-order bit signal of the video signal. A current that is the result of combining the first and second output currents from the first and second current driver circuits is output as an output current. An amount of change in the output current that corresponds to a change of one LSB of the video signal is varied in accordance with the value of the video signal, the gamma characteristic is linearly approximated and the overall luminance of a display panel is controlled based upon a control signal from a luminance adjustment circuit.

### FIELD OF THE INVENTION

This invention relates to a driver circuit for a light-emitting element and to a display device. More particularly, the invention relates to a driver circuit and device that perform a gamma correction.

### BACKGROUND OF THE INVENTION

An arrangement of the kind illustrated in FIG. 13 by way of example is known as an electroluminescent storage device (refer to the specification of Japanese Patent Kokai Publication No. JP-A-2-148687, pages 5 and 6, FIG. 2). As shown in FIG. 13, this conventional electroluminescent device includes an electroluminescent element 40; a plurality of memory cells 22 corresponding to the electroluminescent element 40; a current source 28 (a current mirror comprising transistors 26 and 27); current control means (transistors) 24, which correspond to the plurality of memory cells 22, connected to corresponding ones of the memory cells 22 and responsive to signals, which are held in the memory cells 22, for controlling current that flows from the current source 28 to the electroluminescent element 40; and control logic, a column data register, display input/readout logic and row strobe register, etc., none of which are shown, for supplying the memory cells 22 with signals Bn to B0 representing luminance required by the electroluminescent element 40.

Current corresponding to the signals held in the memory cells 22 flows through transistors 24n to 24n-3, current that is the sum of the currents that flow through the transistors 24n to 24n-3 enters the drain of the transistor 26 constituting the input end of the current source (current mirror) 28, and the mirror current of the input current is output from the drain of the transistor 27, which constitutes the output end of the current source (current mirror), and is supplied to the electroluminescent element 40.

In the arrangement shown in FIG. 13, the relationship between the input data signal and the output current (and therefore luminance) is a positive proportional relationship (gamma value=1.0). Consequently, in order to perform a correction such as one where the gamma value is 2.2, the gamma correction must be applied to the video signal stored in the memory cells 22. Since the human eye is sensitive to dark colors, an image will appear more natural if the luminance of the input signal satisfies a luminance=(signal strength)^{γ} (e.g., γ=1.8, 2.2, etc.) relationship rather than a positive proportional relationship. In general, therefore, the relationship between panel luminance and the video signal is provided with a gamma characteristic.

Generally, in a case where a gamma correction is made, a gamma correction circuit 131 for making the relationship between the input signal (video signal) and luminance conform to the gamma characteristic is provided on the input side of a display element driver circuit 132. The signal that has been gamma-corrected by the gamma correction circuit 131 is input to the display element driver circuit 132, and the data signal is supplied from the display element driver circuit 132 to a display element panel 133 via a data signal line. Since the gamma correction circuit 131 is necessary in this arrangement, however, not only is the circuitry large in size but an additional problem is a reduction of grayscales that can be expressed. For example, if the gamma characteristic (gamma value=2.2) is expressed using an 8-bit (256 grayscales) display element driver circuit 132, only 187 grayscales can be realized.

In order to implement a gamma correction having grayscale (256 grayscales) the same as those of the input signal, on the other hand, it is necessary that the gamma correction circuit 131 and display element driver circuit 132 be capable of supporting more grayscales than those of the input signal, as illustrated in FIG. 15. Consequently, the circuitry is large in size. In the example illustrating in FIG. 15, both the gamma correction circuit 131 and display element driver circuit 132 support 512 grayscales (nine bits).

[Patent Document 1]

Japanese Patent Kokai Publication No. JP-A-2-148687, pages 5 and 6, FIG. 2).

Thus, in a case where the conventional display circuit is provided with a gamma correction function, a problem which arises is the large size of the circuitry, as mentioned above. The same is true also in a case where a gamma correction of grayscales identical with those of the input signal is performed.

### SUMMARY OF THE DISCLOSURE

Accordingly, it is an object of the present invention to provide a driver circuit that makes it possible to reduce the size of circuitry and diminish chip area in realizing a gamma characteristic, as well as to a display device having this driver circuit.

Another object of the present invention is to provide a driver circuit that makes it possible to adjust the overall luminance of a display panel while maintaining the gamma characteristic, as well as a display device having this driver circuit.

The above and other objects are attained by the present invention, which controls a reference current, which flows into a current-source circuit, based upon high- and lower-order bits of a video signal, whereby an input/output characteristic of a circuit that drives a light-emitting element is made to approach a gamma characteristic, for example, thereby making it possible to achieve an optimum display. More specifically, the reference current decides an amount of change in output current with respect to a unit change in the input signal.

According to one aspect of the present invention, there is provided a driver circuit comprising: a current-source circuit for generating a reference current that decides an amount of change in the output current with respect to a unit change in the input signal, wherein the input signal has been partitioned into prescribed lower-order bits and higher-order bits situated above the lower-order bits, the current-source circuit varying the value of the reference current based upon the higher-order bits of the input signal; a first current generating circuit for generating a first output current, which corresponds to the lower-order bit signal of the input signal, based upon the reference current; and a second current generating circuit for generating a second output current, which corresponds to the higher-order bit signal of the input signal, from a current source different from that of the current-source circuit; wherein a current that is the result of combining the first and second output currents is output from an output terminal as the output current, and a characteristic between the input signal that is input to an input terminal and the output current that is output from the output terminal is made a predetermined input/output characteristic of a prescribed non-linearity.

According to the present invention, in a interval in which the higher-order bit signal of the input signal is not changed in value but is made a constant value and only the lower-order bit signal of the input signal is changed in value, the reference current and the second output current are each set to values that correspond to the constant value of the higher-order bit signal of the input signal. Further, according to the present invention, the current value of the output current corresponding to at least one of the above-mentioned intervals of the input signal is set to a current value that corresponds to a logic value of the predetermined input/output characteristic of prescribed non-linearity, and a linear approximation of the non-linear input/output characteristic is carried out on a per-interval basis.

According to another aspect of the present invention, the foregoing objects are attained by providing a driver circuit for a light-emitting element in which emission of light is controlled in accordance with a supplied current, the driver circuit receiving a video signal that enters from an input terminal, generating a current that corresponds to the video signal and outputting the current from an output terminal, the video signal being partitioned into prescribed lower-order bits and higher-order bits situated above the lower-order bits, the driver circuit comprising: a first current driver circuit, which has a plurality of current sources in which values of current that flow through respective ones of the current sources are decided based upon an applied reference current, and switch circuits that on/off control current paths between the plurality of current sources and a current output terminal based upon the lower-order bit signal of the video signal, for generating and outputting a first output current that corresponds to the lower-order bit signal of the video signal; a second current driver circuit for generating and outputting a second output current, which corresponds to the higher-order bit signal of the video signal, from a current source different from that of the reference current; and a current-source circuit, which has a current source that generates the reference current, for varying the output reference current based upon the higher-order bit signal of the video signal; wherein a current that is the result of combining the first and second output currents from the first and second current driver circuits, respectively, is output from the output terminal as the output current, and an amount of change in the output current that corresponds to a change in a unit quantity of the video signal is varied in accordance with the video signal.

According to the another aspect of the present invention, the driver circuit further comprises a luminance adjusting circuit for varying an output control potential based upon a control signal that enters from a control terminal, wherein the current-source circuit receives the control potential that is output from the luminance adjusting circuit and varies the current value of the reference current that is output. Further, in the driver circuit according to this aspect of the present invention, it may be so arranged that the second current driver circuit varies the current value of the second output current based upon the control potential.

The meritorious effects of the present invention are summarized as follows.

In accordance with the present invention, a major reduction in the size of the circuitry is realized by controlling output current upon dividing the video signal into high- and lower-order bits. A driver circuit for a light-emitting element having a gamma characteristic can be realized by a chip of small area.

In accordance with the present invention, the overall luminance of a panel can be adjusted while maintaining the gamma characteristic.

In accordance with the present invention, panel luminance is uniformalized by using the driver circuit of the light-emitting element properly depending upon the color of the light-emitting element.

Still other objects and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a diagram illustrating the structure of a driver circuit for a light-emitting element according to an embodiment of the present invention;

FIG. 2 is a graph illustrating one example of a gamma characteristic according to this embodiment;

FIGS. 3A, 3B and 3C are truth tables for describing the operation of a first current driver circuit, second current driver circuit and current-source circuit, respectively, in FIG. 1;

FIG. 4 is a graph useful in describing a gamma characteristic and an input/output characteristic of the driver circuit for a light-emitting element according to the present invention;

FIG. 5 is a diagram useful in describing operation of a decoder in the driver circuit according to this embodiment;

FIG. 6 is a graph illustrating an example of control of panel luminance according to this embodiment;

FIG. 7 is a diagram illustrating another example of the structure of a current-source circuit used in this embodiment;

FIG. 8 is a diagram illustrating yet another example of the structure of a current-source circuit used in this embodiment;

FIG. 9 is a diagram illustrating an example of the structure of a voltage control circuit in FIG. 8;

FIG. 10 is a diagram illustrating the structure of a display device according to this embodiment;

FIG. 11 is a diagram illustrating the structure of a data driver in FIG. 10;

FIG. 12 is a diagram illustrating the structure of a display device according to the present invention;

FIG. 13 is a diagram illustrating the structure of an electroluminescent display device according to the prior art;

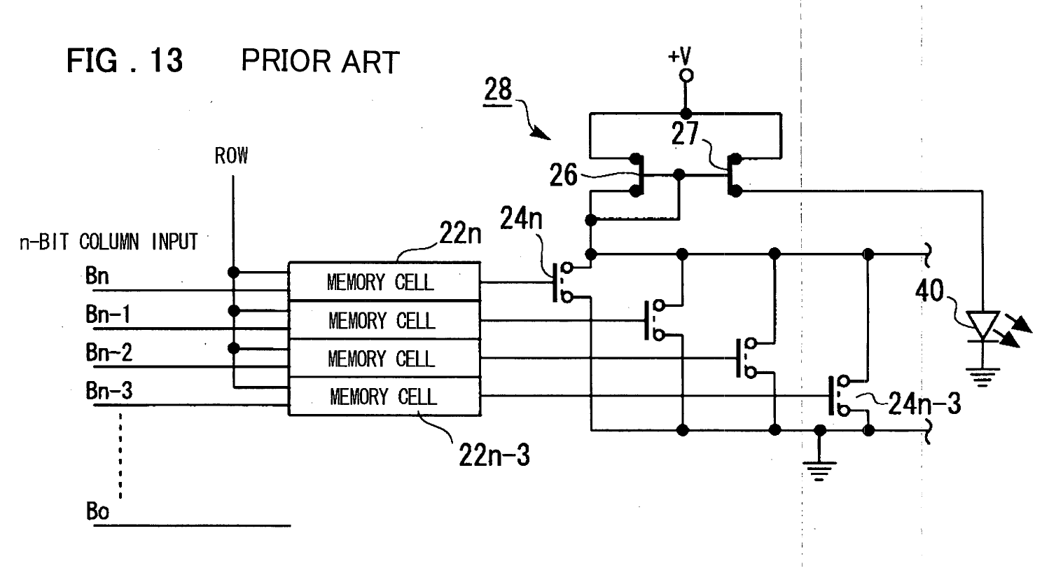

FIG. 14 is a diagram illustrating the structure of a display device having a gamma correction function according to the prior art; and

FIG. 15 is a diagram illustrating the structure of a display device having a gamma correction function according to the prior art.

### PREFERRED EMBODIMENTS OF THE INVENTION

The present invention will be described below with reference to the accompanying drawings.

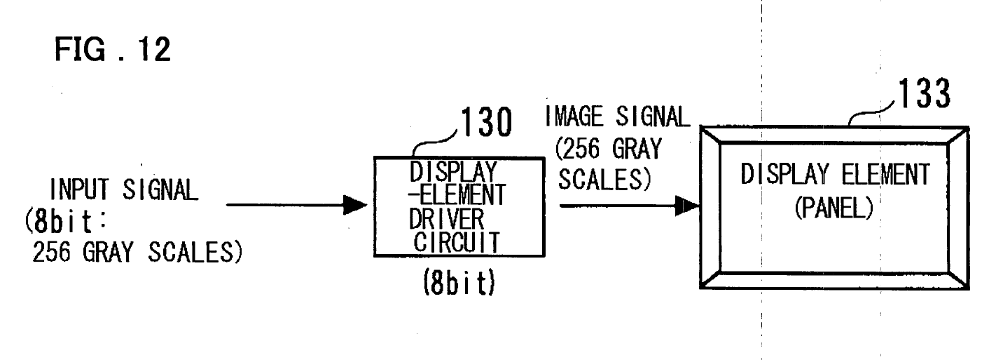

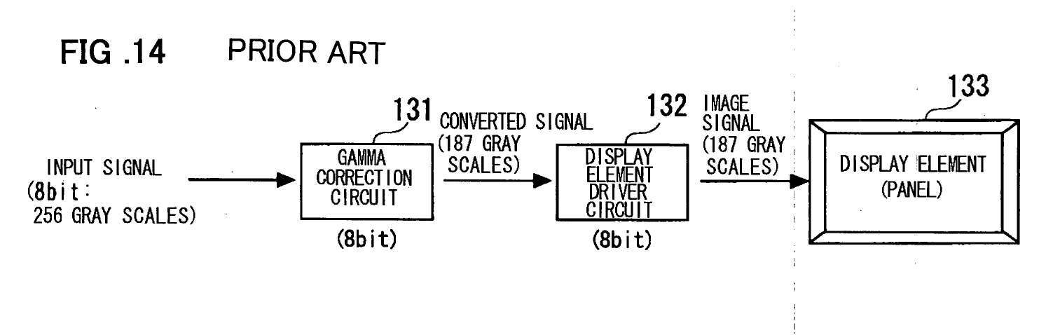

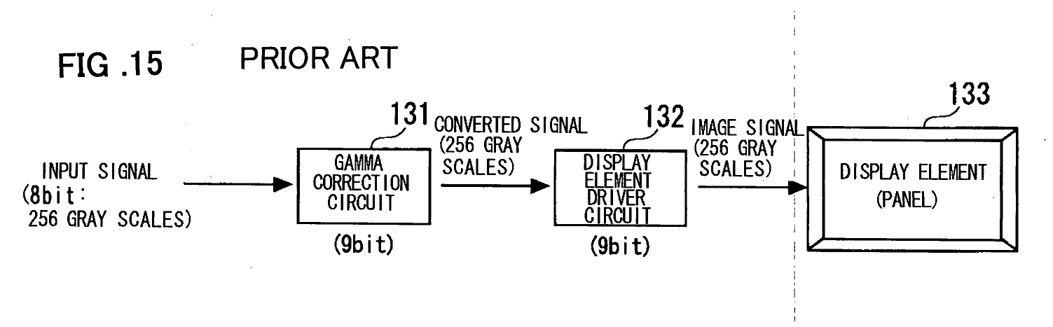

The overall structure of a display device according to an embodiment of the present invention will be described with reference to FIG. 12. The display device incorporates a gamma correction function in a display-element driver circuit 130 to which an input signal (video signal) is applied for driving current through a display element of a display panel. By virtue of this structure, the area of the circuitry and area of the chip when the device is integrated can be reduced in comparison with the conventional structure shown in FIGS. 14 and 15. A further characterizing feature is that the display-element driver circuit 130 supports 256 grayscale levels (represented by eight bits) and is capable of delivering a 256 grayscale input signal to a display element (panel) 133. A gamma correction circuit supporting 512 grayscale levels (represented by nine bits) and a display-element driver circuit supporting nine bits, which are employed in the arrangement of FIG. 15, are unnecessary.

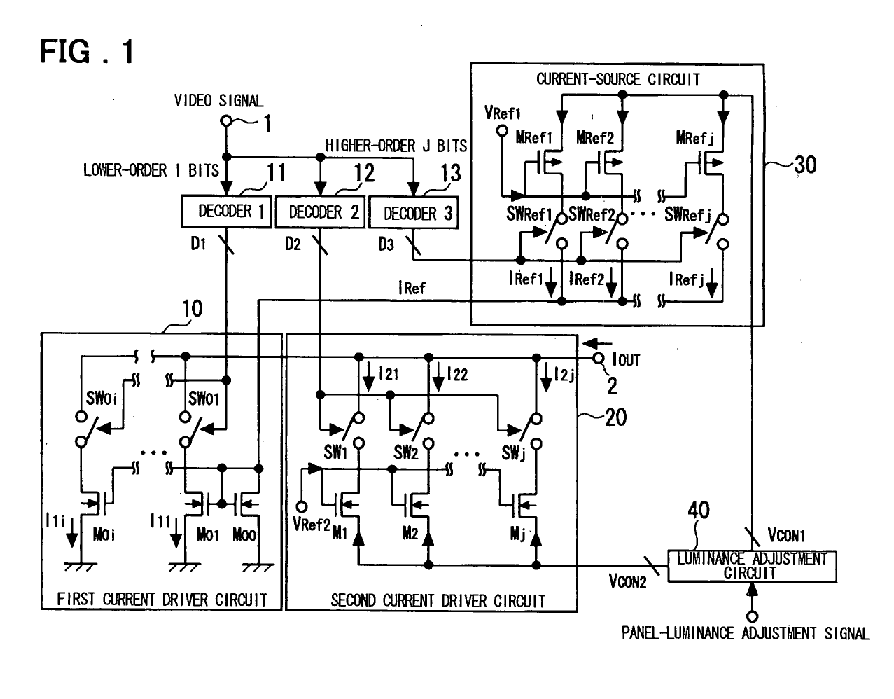

As illustrated in FIG. 1, a driver for a display device according to the present invention comprises: a first current driver circuit (10), which has a plurality of current sources (M₀₀, M₀₁ to M₀ᵢ) for outputting current of a value decided based upon a reference current (I_{REF}) provided by a current-source circuit (30), and switch circuits (SW₀₁ to SW₀ᵢ) that on/off control current paths between the plurality of current sources (M₀₁ to M₀ᵢ) and a current output terminal (2) based upon a prescribed lower-order bit signal (inclusive of the LSB) of a video signal comprising a plurality of bits, for outputting a first output current conforming to the lower-order bit signal of the video signal; a second current driver circuit (20) for outputting a second output current conforming to a prescribed higher-order bit signal (inclusive of the MSB) of the video signal; and the current-source circuit (30), which has a current source that generates the reference current (I_{REF}) based upon the prescribed higher-order bit signal of the video signal, for varying the reference current (I_{REF}) based upon the value of the video signal. A current that is the result of combining the first and second output currents from the first and second current driver circuits is output from the output terminal (2) as an output current (I_{OUT}). In the display-device driver according to the present invention, an amount of change in the output current (I_{OUT}) that corresponds to a change in unit value of the video signal is varied in accordance with the value of the video signal, and the input/output characteristic of output current with respect to the video signal has a desired characteristic. By changing the reference current (I_{REF}), which is for outputting a driving current conforming to the video signal, in accordance with the value of the higher-order bits of the video signal (grayscale), the increment (amount of change in units of the LSB) in output current of the driver circuit is varied, whereby a gamma characteristic having a gamma value of 2.2 or the like can be approximated with a piecewise linear approximation method. In accordance with the embodiment, the precision of the gamma-correction approximation declines in the first current driver circuit (10) and current-source circuit (30) in comparison with the case where the output current is varied using all bits of the video signal. The size of the circuitry, however, is greatly reduced. The range of the video signal (grayscale) from minimum to maximum values thereof is divided into a plurality of intervals, the first output current is made zero and the second output current is made the output current at least at one end of one interval. As a result, agreement with an ideal value can be achieved at the interval end with respect to the desired non-linear characteristic, and the piecewise linear approximation is realized while simplifying structure and reducing the size of the circuitry.

In accordance with this mode of practicing the invention, the overall luminance of the display panel can be varied by varying the reference current (I_{REF}) and/or second output current based upon an applied panel-luminance adjustment signal. Specifically, by multiplying the overall current of the current source several-fold using the luminance adjustment signal, overall luminance adjustment of the panel can be performed while maintaining the gamma characteristic. Furthermore, in accordance with the present invention, the relationship between luminance and current of a light-emitting element has a characteristic that differs from color to color. Uniformity of panel luminance, therefore, is achieved by adjusting the current, which is supplied from the driver circuit of the light-emitting element, for each color of the light-emitting element.

The present invention will now be described in greater detail with reference to the drawings illustrating a preferred embodiment to which the invention is applied.

FIG. 1 is a diagram illustrating the configuration of a driver circuit for a light-emitting element according to an embodiment of the present invention. As shown in FIG. 1, the driver circuit includes a first current driver circuit 10, a second current driver circuit 20, a current-source circuit 30, decoders 11, 12 and 13, and a luminance adjustment circuit 40.

The decoder 11 receives lower-order I bits of a K-bit video signal (input signal) input from an input terminal 1 and outputs a decoded signal D1.

The decoder 12 receives higher-order J bits (J=K−I) of the K-bit video signal (input signal) and outputs a decoded signal D2.

The decoder 13 receives higher-order J bits (J=K−I) of the K-bit video signal (input signal) and outputs a decoded signal D3.

The first current driver circuit 10 includes switches SW₀₁ to SW₀ᵢ, having one terminals connected in common to an output terminal 2 and having control terminals to which are supplied the decoded signal D1 of i bits (the bit width is i) output from the decoder 11; NMOS transistors M₀₁ to M₀ᵢ having drains connected to the other terminals of the switches SW₀₁ to SW₀ᵢ, respectively, sources connected to a ground potential and gates tied together; and an NMOS transistor M₀₀ having a drain and gate tied together and connected to the gates of the NMOS transistors M₀₁ to M₀ᵢ and a source connected to the ground potential. The NMOS transistors M₀₁ to M₀ᵢ compose a multiple-output type current mirror circuit. A reference current that is output from the current-source circuit 30 is input to the drain of the NMOS transistor Moo, and the sum of the mirror currents is output from the drains of those NMOS transistors among the NMOS transistors M₀₁ to M₀ᵢ that are connected to those switches SW₀₁ to SW₀ᵢ that have been turned on.

The second current driver circuit 20 includes switches SW₁ to SWⱼ having control terminals to which are supplied the decoded signal D2 of J bits (the bit width is J) output from the decoder 12, and NMOS transistors M₁ to Mⱼ having drains connected to the other terminals of the switches SW₁ to SWⱼ, respectively, sources tied together and connected to a potential V_{CON2} and gates tied together and connected to a second reference potential V_{REF2}.

The current-source circuit 30 includes PMOS transistors M_{Ref1} to M_{Refj} having sources tied together and connected to a potential V_{CON1} and gates tied together and connected to a first potential V_{REF1}, and switches SW_{Ref1} to SW_{Refj} having one ends connected to the drains of the PMOS transistors M_{Ref1} to M_{Refj}, respectively, and control terminals to which the J-bit decoded signal D3 output from the decoder 13 is input. The other ends of the switches SW_{Ref1} to SW_{Refj} are tied together and connected to the drain of the NMOS transistor M₀₀ of the first current driver circuit 10 (i.e., to the input end of the current mirror circuit).

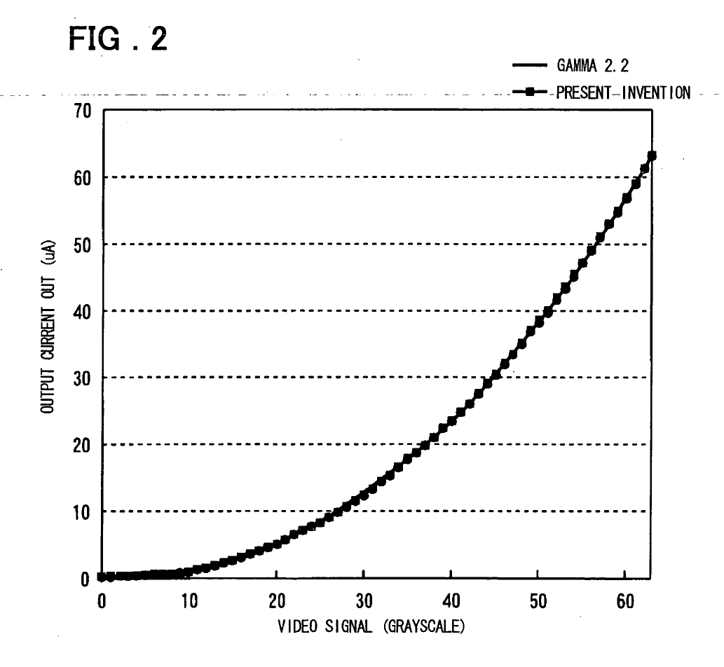

According to the present embodiment, the input/output characteristic of the driver circuit for the light-emitting element (the characteristic of grayscales vs. output current) is brought close to a gamma characteristic of the kind shown in FIG. 2, with piecewise linear approximation of the gamma characteristic, thereby realizing the gamma characteristic.

The higher-order J-bit signal of the video signal is converted by the decoder 3, and the current-source circuit 30 supplies the reference current I_{Ref}, which flows into the first current driver circuit 10, based upon the signal obtained by the conversion.

By varying the reference current I_{Ref} by the higher-order bits of the video signal, an increment in output current corresponding to one grayscale (one LSB) at a certain grayscale can be changed.

The current-source circuit 30 is provided with reference-current sources that are capable of realizing 2^{J} kinds of current values associated with the higher-order J-bit signal (which takes on values of 2^{J} sets) of the video signal. The common voltage V_{Ref1} is input to the gates of the PMOS transistors M_{Ref1} to M_{Refj}. As a result, the current that flows into each of the transistors (current sources) is adjusted by weighting the aspect ratio (channel width/channel length) of the transistor.

The potential V_{CON1} output from the panel luminance adjustment circuit 40 is capable of changing the reference current I_{Ref} of the current-source circuit 30. The luminance of the light-emitting element (e.g. an electroluminescent element) (not shown) varies in proportion to the value of the current that flows into the light-emitting element. The overall luminance of the panel, therefore, can be adjusted by controlling the source potential of the PMOS transistors M_{Ref1} to M_{Refj} of the current-source circuit 30.

Though the gate potentials of the current-source transistors M_{Ref1} to M_{Refj} in the current-source circuit 30 shown in FIG. 1 are made a common potential, the present invention is not limited to such an arrangement.

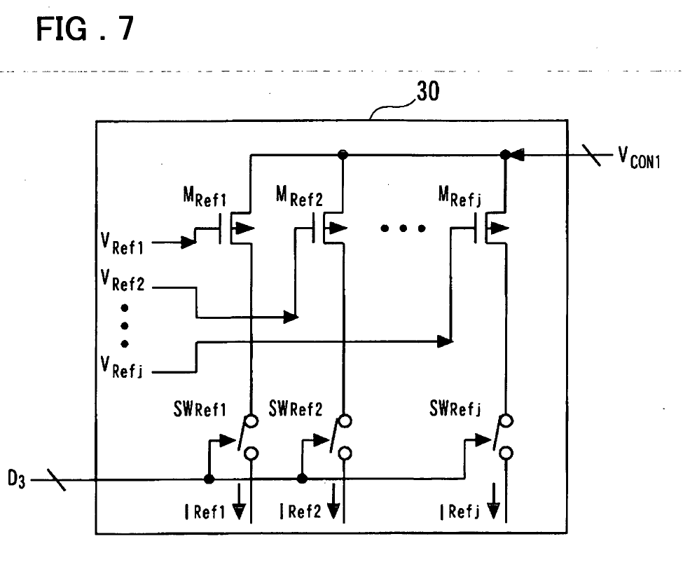

Another example of an arrangement for the current-source circuit 30 is as illustrated in FIG. 7. Here the gate potentials V_{Ref1} to V_{Refj} of the PMOS transistors M_{Ref1} to M_{Refj}, respectively, are set individually.

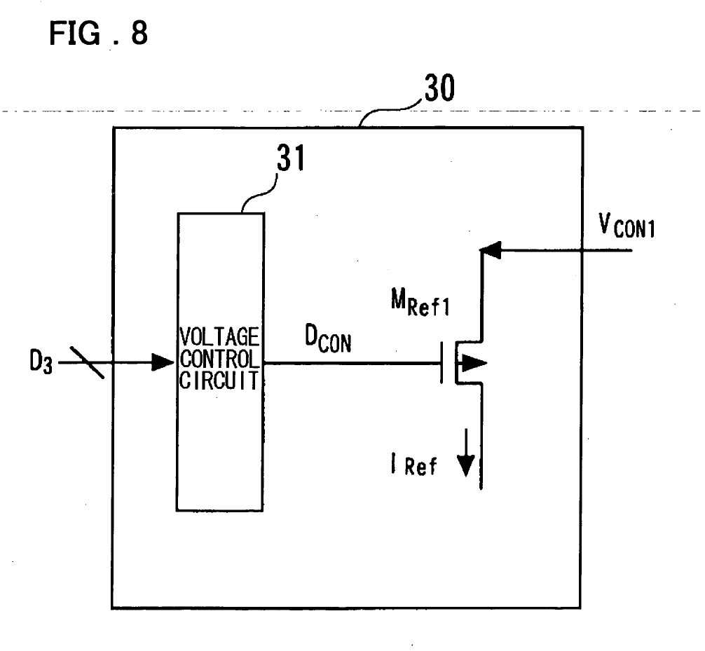

In an alternative arrangement of the current-source circuit 30, as shown in FIG. 8, the current-source circuit 30 is provided with a voltage control circuit 31 for selecting, on the basis of the output signal D3 from the decoder 13, a potential D_{CON} that is applied to the gate of one PMOS transistor M_{Ref1} constituting the current source.

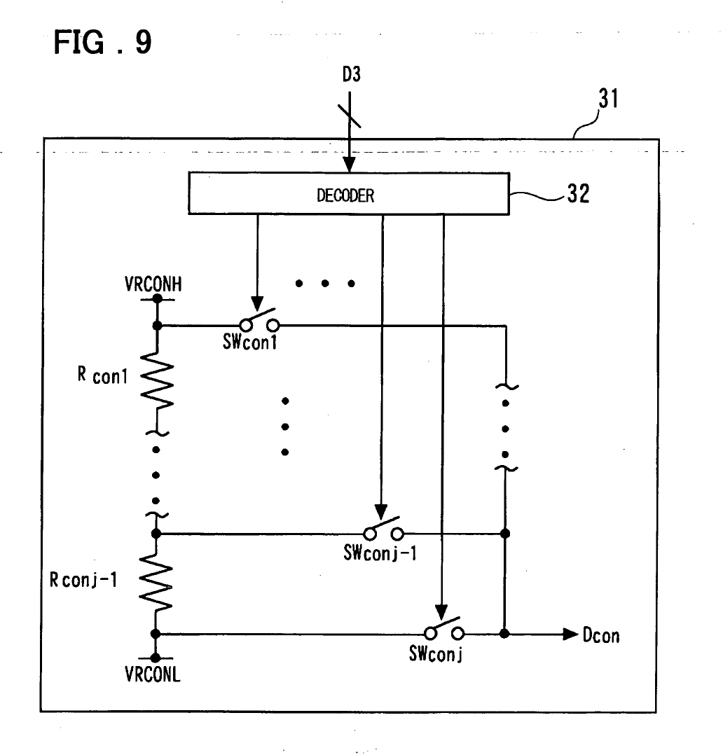

FIG. 9 is a diagram illustrating one example of the structure of the voltage control circuit 31 shown in FIG. 8. As shown in FIG. 9, the voltage control circuit 31 includes a resistor string comprising resistors R_{con1} to R_{conj-1} connected serially between a high reference potential V_{RCONH} and a low reference potential V_{RCONL}, and switches SW_{con1} to SW_{conj}, which are connected between an output terminal D_{con} and nodes (taps) of the reference potentials V_{RCONH} and V_{RCONL} and resistors R_{con1} to R_{conj-1}, each switch having a control terminal to which is input an output signal from a decoder 32 the input of which is the signal D3. By turning the switches R_{con1} to R_{conj} on and off, the gate voltage necessary for the current-source transistor M_{Ref1} of the current-source circuit 30 is selected and output from the output terminal D_{con}.

With reference again to FIG. 1, the first current driver circuit 10 generates an output of one interval that is the result of partitioning the gamma characteristic by the reference current I_{ref}, which is output from the current-source circuit 30, and the signal D1 that is output from the decoder 11.

The lower-order I-bit signal of the video signal is input to and decoded by the decoder 11. As a result, the width of the interval that is the result of piecewise linear approximation of the gamma characteristic is I bits (2^{I} grayscale levels).

In a case where the NMOS transistors M₀₀ to M₀ᵢ of the first current driver circuit 10 have undergone binary weighting, the decoder 11 is not provided and the lower-order I bits of the video signal are can be used directly as the control signal of the switches SW₀₁ to SW₀ᵢ.

More specifically, if the NMOS transistors M₀₀ to M₀ᵢ are subjected to binary weighting, the aspect ratios of the NMOS transistors M₀₀ to M₀ᵢ are made 2⁰, 2¹, . . . , 2⁽ⁱ⁻¹⁾, with 1=2⁰ holding for the NMOS transistor M₀₀.

The second current driver circuit 20 controls the output current I_{OUT} that prevails when a carry operation has been performed by the first current driver circuit 10.

The first current driver circuit 10 generates the first output current based upon the lower-order I-bit signal of the video signal. When the video signal has a value of 2^{I}, therefore, the output current (=I_{OUT1}) of the first current driver circuit 10 becomes zero.

Accordingly, a current obtained when a carry operation has been performed by the second current driver circuit 20 is supplied. The second current driver circuit 20 outputs the second current, which corresponds to the higher-order J-bit signal of the video signal. In the second current driver circuit 20, the common gate voltage V^{REF2} is applied to the transistors M₁ to Mⱼ, and the current that flows into each transistor is adjusted by changing the aspect ratio. Further, the source voltage of the transistors M₁ to Mⱼ is changed by the potential V_{CON2} from the luminance adjustment circuit 40, thereby controlling the output current from the second current driver circuit 20 and adjusting the overall luminance of the panel.

The second current driver circuit 20 also may have the circuit structure shown in FIG. 7 or 8 as a matter of course. In the example shown in FIG. 1, the output current I_{OUT} from the output terminal 2 is output as a sink current. However, it is of course permissible to adopt an arrangement in which the current is output as a source current. In this case, the current mirror circuit (M₀₀ to M₀ᵢ) constituting the current source of the first current driver circuit 10 would be composed by PMOS transistors (PMOS current sources) instead of NMOS transistors, the current sources (M₁ to Mⱼ) of the second current driver circuit 20 also would be composed by PMOS current sources, and the current sources (M_{ref1} to M_{refj}) of the current-source circuit 30 would be composed by NMOS current sources.

An example of the design specifications of a driver circuit for realizing 64 grayscales (2⁶ grayscales) will be described with reference to Table 1 below. The Table includes, in list form, interval, video signal (grayscale), current value at gamma 2.2, I_{OUT} (the output current at output terminal 2 in FIG. 1), I_{Ref} (reference current from the current-source circuit 30 of FIG. 1) and I_{OUT2} (output current from the second current driver circuit 20 of FIG. 1).

According to these design specifications, the video signal is partitioned into three higher-order bits (J=3 in FIG. 1) and three lower-order bits (1=3 in FIG. 1), the input/output characteristic of the driver circuit for the light-emitting element is partitioned into eight (=2³) intervals, and a piecewise linear approximation to the gamma characteristic is performed.

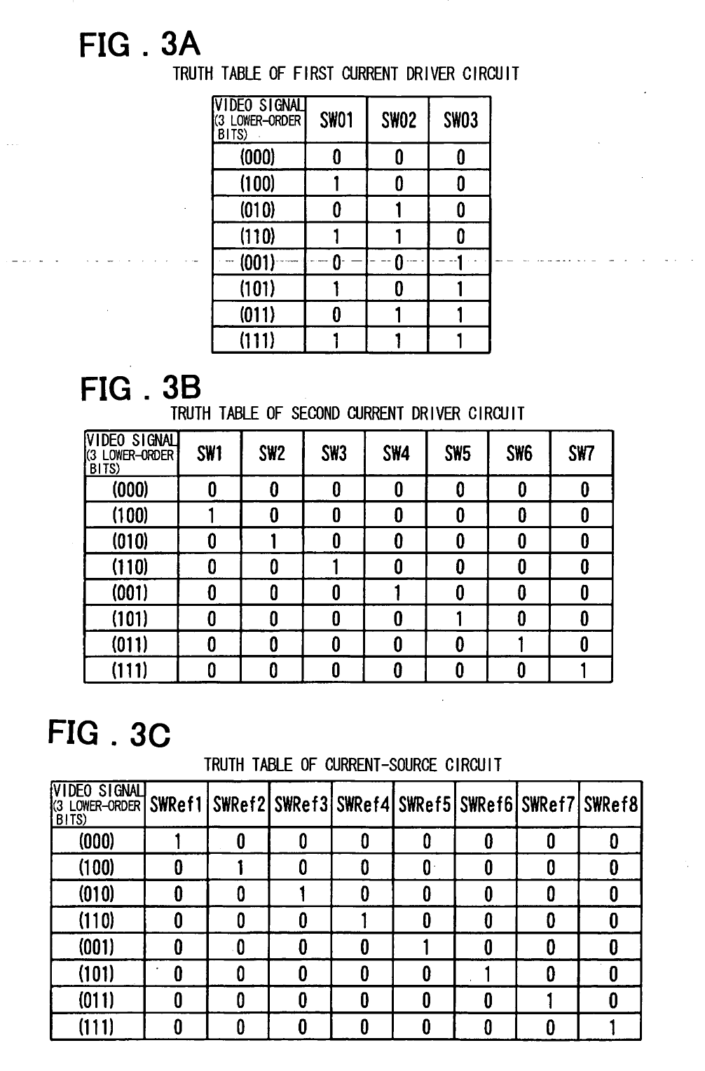

FIGS. 3A, 3B and 3C illustrate examples of truth tables for describing the operation of the first current driver circuit 10, second current driver circuit 20 and current-source circuit 30. The design values of the current sources are illustrated in list form in Table 1. FIGS. 3A to 3C illustrate the relationship between the values of the video signal (binary values of three bits) and the ON/OFF states of the switches. A “1” indicates that the corresponding switch is ON, and a “0” indicates that the corresponding switch is OFF.

TABLE 1

| INTERVAL | VIDEO SIGNAL | GAMMA 2.2 (uA) | IOUT (uA) | IRef (uA) | IOUT2 (uA) |
|---|---|---|---|---|---|
| 1 | 0 | 0.00 | 0.00 | 0.07 | 0.00 |
| | 1 | 0.01 | 0.07 | | |
| | 2 | 0.03 | 0.14 | | |
| | 3 | 0.08 | 0.21 | | |
| | 4 | 0.15 | 0.29 | | |
| | 5 | 0.24 | 0.36 | | |
| | 6 | 0.36 | 0.43 | | |
| | 7 | 0.50 | 0.50 | | |
| 2 | 8 | 0.67 | 0.67 | 0.29 | 0.67 |
| | 9 | 0.87 | 0.96 | | |
| | 10 | 1.10 | 1.25 | | |
| | 11 | 1.35 | 1.53 | | |
| | 12 | 1.64 | 1.82 | | |
| | 13 | 1.96 | 2.11 | | |
| | 14 | 2.30 | 2.39 | | |
| | 15 | 2.68 | 2.68 | | |
| 3 | 16 | 3.09 | 3.09 | 0.54 | 3.09 |
| | 17 | 3.53 | 3.63 | | |
| | 18 | 4.00 | 4.17 | | |
| | 19 | 4.51 | 4.71 | | |
| | 20 | 5.05 | 5.25 | | |
| | 21 | 5.62 | 5.79 | | |
| | 22 | 6.22 | 6.32 | | |
| | 23 | 6.86 | 6.86 | | |
| 4 | 24 | 7.54 | 7.54 | 0.81 | 7.54 |
| | 25 | 8.25 | 8.35 | | |
| | 26 | 8.99 | 9.17 | | |
| | 27 | 9.77 | 9.98 | | |
| | 28 | 10.58 | 10.79 | | |
| | 29 | 11.43 | 11.61 | | |
| | 30 | 12.32 | 12.42 | | |
| | 31 | 13.24 | 13.24 | | |
| 5 | 32 | 14.19 | 14.19 | 1.11 | 14.19 |
| | 33 | 15.19 | 15.30 | | |
| | 34 | 16.22 | 16.41 | | |
| | 35 | 17.29 | 17.51 | | |
| | 36 | 18.39 | 18.62 | | |
| | 37 | 19.54 | 19.72 | | |
| | 38 | 20.72 | 20.83 | | |
| | 39 | 21.93 | 21.93 | | |
| 6 | 40 | 23.19 | 23.19 | 1.41 | 23.19 |
| | 41 | 24.49 | 24.60 | | |
| | 42 | 25.82 | 26.01 | | |
| | 43 | 27.19 | 27.42 | | |
| | 44 | 28.60 | 28.84 | | |
| | 45 | 30.05 | 30.25 | | |
| | 46 | 31.54 | 31.66 | | |
| | 47 | 33.07 | 33.07 | | |
| 7 | 48 | 34.64 | 34.64 | 1.73 | 34.64 |
| | 49 | 36.24 | 36.36 | | |
| | 50 | 37.89 | 38.09 | | |
| | 51 | 39.58 | 38.82 | | |
| | 52 | 41.30 | 41.55 | | |
| | 53 | 43.07 | 43.27 | | |
| | 54 | 44.88 | 45.00 | | |
| | 55 | 46.73 | 46.73 | | |
| 8 | 56 | 48.62 | 48.62 | 2.05 | 48.62 |
| | 57 | 50.55 | 50.67 | | |
| | 58 | 52.52 | 52.73 | | |
| | 59 | 54.53 | 54.78 | | |
| | 60 | 56.59 | 56.84 | | |
| | 61 | 58.68 | 58.89 | | |
| | 62 | 60.82 | 60.95 | | |
| | 63 | 63.00 | 63.00 | | |

In Table 1 above, gamma 2.2 is the value of a gamma curve. That is, we have the following:
gamma 2.2=I_{MAX}×(video signal/number of grayscales)^{2.2} (1)

In the design specifications illustrated in Table 1, it is so arranged that a current of 63 uA will flow at the time of the 63rd grayscale. Therefore, we have the following:
gamma 2.2=63 uA×(video signal/63 grayscale)^{2.2} (2)

The reference current I_{Ref1} of Interval 1 is a reference current equivalent to one LSB in the interval from grayscale 0 to grayscale 7. It will suffice if an output current I_{OUT} of 0.50 uA flows at the time of grayscale 7 in Interval 1. The reference current I_{Ref}, therefore, is 0.50÷7=0.0714=0.07 uA. The output current I_{OUT1} of the first current driver circuit 10 in interval 1 is as follows:
I_{OUT1}=0.07 uA×video signal (three lower-order bits)
(In Table 1, the numerical values are arranged such that the number of effective decimal places is made the second decimal place uniformly.) Further, the output current I_{OUT2} of the second current driver circuit 20 in Interval 1 is 0 uA, and therefore the output current I_{OUT} of the driver circuit for the light-emitting element is as follows:
I_{OUT}=I_{OUT1}+I_{OUT2}=0.07 uA×video signal (three lower-order bits) (3)

In a case where the video signal has a value of 8, the reference current changes over from I_{Ref1} to I_{Ref2} in accordance with FIGS. 3A to 3C. This is accompanied by output of I_{OUT2} from the second current driver circuit 20 as an output current equivalent to the carry operation. Accordingly, when the video signal has a value of 8, the output current I_{OUT} is as follows:
I_{OUT}=I_{Ref2}×0 (three lower-order bits of the video signal)+I_{OUT2}=0.67 uA (4)

The first term is the output current of the first current driver circuit 10, and the second term is the output current of the second current driver circuit 20. From this the output current I_{OUT2} of the second current driver circuit 20 is 0.67 uA. Further, the reference current I_{Ref2} is a reference current of Interval 2 (from grayscale 8 to grayscale 15). The reference current I_{Ref2} is given by the following:
[(gamma 2.2 of 15^{th} grayscale)−(output current I_{OUT} of element driver circuit of eighth grayscale)]÷7]=(2.68 uA−0.67 uA)÷7=0.29 uA (5)

Accordingly, the output current I_{OUT} in Interval 2 is
I_{OUT}=I_{Ref2}×video signal (three lower-order bits)+I_{OUT2}=0.29 uA×video signal (three lower-order bits)+0.67 uA (6)

Similarly, when reference current I_{Ref3}, reference current I_{Ref4}, and output current I_{OUT2} of the second current driver circuit are found, the results are as shown in Table 1.

In the present embodiment, the maximum current I_{MAX} of output current I_{OUT} can be changed using the panel luminance adjustment signal.

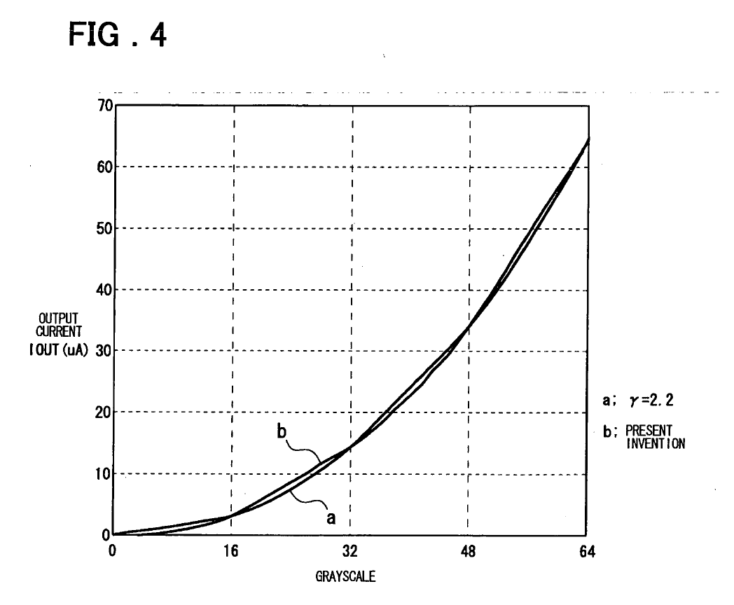

Other design specifications will now be described. Reference will be had to FIG. 4 to describe a case where grayscale 0 to 63 are partitioned equally into four intervals 1 to 4. In the graph of FIG. 4, curve a represents a gamma curve (gamma value=2.2) and curve b an input/output characteristic (piecewise linear interpolation characteristic) of a 64-grayscale element driver circuit according to the present invention. As illustrated in FIG. 4, the input/output characteristic b of the driver circuit for a 64-grayscale (grayscale 0 to 63) light-emitting element according to the invention is set in such a manner that the output current I_{OUT} at the beginning and end of each interval will agree with the value (γ-=2.2) of the gamma curve, where the characteristic is divided into a total of four intervals of grayscale 0 to 15, 16 to 31, 32 to 47 and 48 to 63. By exercising control to vary the value of reference current I_{ref} between intervals, the change (slope or gradient) in output current with respect to a change in one grayscale (one LSB of the video signal) will differ and a piecewise linear approximation is achieved. Further, output current between intervals also makes a continuous transition, as in the manner of the output current at grayscale 15 in Interval 1, output current at grayscale 16 in Interval 2, etc. An excellent approximation is thus realized. It should be noted that in each interval the gamma curve a (γ=2.2) defines a convex curve below the approximation b according to the invention.

In the design specifications of the present embodiment, a 6-bit video signal is partitioned into four lower-order bits and two higher-order bits. The first current driver circuit 10 of FIG. 1 outputs an output current that conforms to the lower-order 4-bit signal, the second current driver circuit 20 outputs an output current that conforms to the higher-order 2-bit signal in conformity with the four intervals, and the current-source circuit 30 variably controls the I_{Ref} based upon the two higher-order bits in conformity with the four intervals. A Table 2 below includes, in list form, interval, video signal (grayscale), current value at gamma 2.2, I_{OUT} (output current), I_{OUT1} (first output current), I_{Ref} (reference current) and I_{OUT2} (second output current).

TABLE 2

| INTERVAL | VIDEO SIGNAL | GAMMA 2.2 (uA) | IOUT (uA) | IOUT1 (uA) | IRef (uA) | IOUT2 (uA) |
|---|---|---|---|---|---|---|
| 1 | 0 | 0.00 | 0.00 | 0.00 | 0.18 | 0.00 |
| | 1 | 0.01 | 0.18 | 0.18 | | |
| | 2 | 0.03 | 0.36 | 0.36 | | |
| | 3 | 0.08 | 0.54 | 0.54 | | |
| | 4 | 0.15 | 0.71 | 0.71 | | |
| | 5 | 0.24 | 0.89 | 0.89 | | |
| | 6 | 0.36 | 1.07 | 1.07 | | |
| | 7 | 0.50 | 1.25 | 1.25 | | |
| | 8 | 0.67 | 1.43 | 1.43 | | |
| | 9 | 0.87 | 1.61 | 1.61 | | |
| | 10 | 1.10 | 1.79 | 1.79 | | |
| | 11 | 1.35 | 1.97 | 1.97 | | |
| | 12 | 1.64 | 2.14 | 2.14 | | |
| | 13 | 1.96 | 2.32 | 2.32 | | |
| | 14 | 2.30 | 2.50 | 2.50 | | |
| | 15 | 2.68 | 2.68 | 2.68 | | |
| 2 | 16 | 3.09 | 3.09 | 0.00 | 0.68 | 3.09 |
| | 17 | 3.53 | 3.77 | 0.68 | | |
| | 18 | 4.00 | 4.44 | 1.35 | | |
| | 19 | 4.51 | 5.12 | 2.03 | | |
| | 20 | 5.05 | 5.80 | 2.71 | | |
| | 21 | 5.62 | 6.47 | 3.38 | | |
| | 22 | 6.22 | 7.15 | 4.06 | | |
| | 23 | 6.86 | 7.82 | 4.74 | | |
| | 24 | 7.54 | 8.50 | 5.41 | | |
| | 25 | 8.25 | 9.18 | 6.09 | | |
| | 26 | 8.99 | 9.85 | 6.77 | | |
| | 27 | 9.77 | 10.53 | 7.44 | | |
| | 28 | 10.58 | 11.21 | 8.12 | | |
| | 29 | 11.43 | 11.88 | 8.79 | | |
| | 30 | 12.32 | 12.56 | 9.47 | | |
| | 31 | 13.24 | 13.24 | 10.15 | | |
| 3 | 32 | 14.19 | 14.19 | 0.00 | 1.26 | 14.19 |
| | 33 | 15.19 | 15.45 | 1.26 | | |
| | 34 | 16.22 | 16.71 | 2.52 | | |
| | 35 | 17.29 | 17.97 | 3.77 | | |
| | 36 | 18.39 | 19.23 | 5.03 | | |
| | 37 | 19.54 | 20.49 | 6.28 | | |
| | 38 | 20.72 | 21.74 | 7.55 | | |
| | 39 | 21.93 | 23.00 | 8.81 | | |
| | 40 | 23.19 | 24.26 | 10.07 | | |
| | 41 | 24.49 | 25.52 | 11.32 | | |
| | 42 | 25.82 | 26.78 | 12.58 | | |
| | 43 | 27.19 | 28.04 | 13.84 | | |
| | 44 | 28.60 | 29.29 | 15.10 | | |
| | 45 | 30.05 | 30.55 | 16.36 | | |
| | 46 | 31.54 | 31.81 | 17.62 | | |
| | 47 | 33.07 | 33.07 | 18.87 | | |
| 4 | 48 | 34.64 | 34.19 | 0.00 | 1.89 | 34.64 |
| | 49 | 36.24 | 36.53 | 1.89 | | |
| | 50 | 37.89 | 38.42 | 3.78 | | |
| | 51 | 39.58 | 40.31 | 5.67 | | |
| | 52 | 41.30 | 42.20 | 7.56 | | |
| | 53 | 43.07 | 44.09 | 9.45 | | |
| | 54 | 44.88 | 45.98 | 11.35 | | |
| | 55 | 46.73 | 47.87 | 13.24 | | |
| | 56 | 48.62 | 49.76 | 15.13 | | |
| | 57 | 50.55 | 51.65 | 17.02 | | |
| | 58 | 52.52 | 53.55 | 18.91 | | |
| | 59 | 54.53 | 55.44 | 20.80 | | |
| | 60 | 56.59 | 57.33 | 22.69 | | |
| | 61 | 58.68 | 59.22 | 24.58 | | |
| | 62 | 60.82 | 61.11 | 26.47 | | |
| | 63 | 63.00 | 63.00 | 28.36 | | |

In Table 2 above, gamma 2.2 is the value of a gamma curve and is given by gamma 2.2=I_{MAX}×(video signal/number of grayscales)^{2.2}, where I_{MAX} of the output current I_{OUT} is the maximum value of the current. In the present embodiment, we have the following:
gamma 2.2=63 uA×(video signal /63 grayscales)^{2.2} (7).

As indicated in Table 2, the reference currents I_{Ref} in Intervals 1 to 4 are assumed to be 0.18 uA, 0.68 uA, 1.26 uA and 1.89 uA, and the second output current I_{OUT2} that is added to the first output current I_{OUT1} is set to 0, 3.09 uA, 14.19 uA and 34.64 uA.

The set values of the reference current I_{Ref} and output current I_{OUT2} will now be described. In Interval 1, the reference current I_{Ref} is a reference current for video signals from 0 to 15 (grayscale 0 to 15). Accordingly, it will suffice if an output current I_{OUT} of 2.68 uA flows at grayscale 15. The reference current in Interval 1, therefore, is expressed as follows (see Table 2):
I_{Ref}=2.68 uA/15=0.18 uA (8)

The output current I_{OUT1} of the first current driver circuit 10 in Interval 1 is as follows:
I_{OUT1}=0.18 uA×video signal (four lower-order bits) (9)

The second output current I_{OUT2} of the second current driver circuit 20 is 0 uA, and therefore the output current I_{OUT} of the driver circuit for the light-emitting element is as follows:
I_{OUT}=I_{OUT1}+I_{OUT2}=0.18 uA×video signal (four lower-order bits) (10)

In a case where the video signal has a value of 16 (grayscale 16) in Interval 2, the four lower-order bits of the video signal are “0”s (binary value=“0000”). Since the first current driver circuit 10 (see FIG. 1) corresponds to the four lower-order bits of the video signal, switches SW1 to SW4 are turned off, as a result of which the first output current I_{OUT1} becomes 0 uA. The second current driver circuit 20 outputs the second output current I_{OUT2}, which corresponds to the two higher-order bits of the video signal. The value (logic value) of gamma 2.2 at grayscale 16 is 3.09 uA. Therefore, the second output current I_{OUT2} of the second current driver circuit 20 in Interval 2 is 3.09 uA.

Accordingly, the output current I_{OUT} of the driver circuit for the light-emitting element is as follows:
I_{OUT}=I_{OUT1}+I_{OUT2}=3.09 (11)

On the basis of Table 2 above, gamma 2.2 at grayscale 16 is 3.09 uA and gamma 2.2 at grayscale 31 is 13.24 uA. The reference current I_{Ref} in Interval 2 from grayscale 16 to grayscale 31, therefore, is as follows:
I_{Ref}=(13.24 uA−3.09 uA)/15=0.68 uA (12)

Since the output of the second current driver circuit 20 in Interval 2 is 3.09, the output current I_{OUT} of the driver circuit for the light-emitting element is as follows:
I_{OUT}=I_{OUT1}+I_{OUT2}=0.68 uA×video signal (value of four low order bits)+3.09 uA (13)

Similarly, with regard to Intervals 3 and 4, the reference current I_{Ref} and the second output current I_{OUT} of the second current driver circuit 20 can be found.

In the design specifications of Table 2 above, 64 grayscales are partitioned equally into four intervals. However, the invention is not limited to these specifications. It goes without saying that the number of intervals, the widths of the intervals, the number of currents in the current-source circuit 30 and the numbers of current sources in the first current driver circuit 10 and second current driver circuit 20 can be set at will in accordance with the number of grayscale levels.

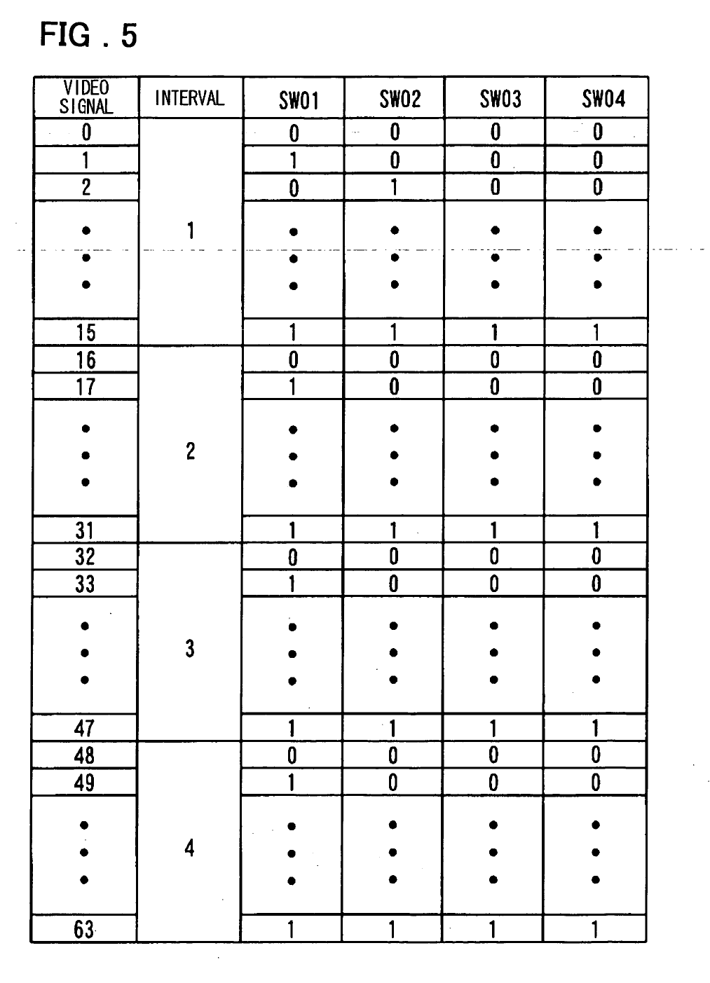

FIG. 5 is a diagram illustrating a truth table useful in describing an example of operation of the decoder 11 (see FIG. 1) for controlling the first current driver circuit 10 that outputs the output current (I_{OUT1}), which corresponds to the four lower-order bits, in a case where 64 grayscales (represented by six bits of the video signal) have been partitioned equally into four intervals in the manner illustrated in Table 2 above. In the example shown in FIG. 5, it is assumed that the switches SW₀₁ to SW₀ᵢ of the first current driver circuit 10 in FIG. 1 are the four switches SW₀₁ to SW₀₄ and that the PMOS transistors M₀₁ to M₀ᵢ are M₀₁ to M₀₄. It should be noted that the four intervals in which the 64 grayscales have been equally divided are decided by the two higher-order bits of the 6-bit video signal, and that the second current driver circuit 20 outputs the second output current corresponding to the two higher-order bits of the 6-bit video signal.

As shown in FIG. 5, values of 0 to 15 (grayscale 0 to 15) of the video signal constitute Interval 1, the switches SW₀₁ to SW₀₄ of the first current driver circuit 10 are turned on in conformity with the binary “1” logic of the four lower-order bits of the video signal. At a video signal value of 15, all of these switches are turned on and the first output current (I_{OUT1}) becomes
I_{Ref}×15.

Values of 16 to 31 (grayscale 16 to grayscale 31) of the video signal constitute Interval 2. With a video signal 16 (the four lower-order bits are all “0”s), the switches SW₀₁ to SW₀₄ of the first current driver circuit 10 are all turned off and the first output current (I_{OUT1}) becomes 0 uA. With video signal values of 17 to 31, the switches SW₀₁ to SW₀₄ of the first current driver circuit 10 are turned on in conformity with the binary “1” logic of the four lower-order bits of the video signal. At a video signal value of 31, all of these switches are turned on and the first output current (I_{OUT1}) becomes
I_{Ref}×15.
Similar control is carried out with regard to Intervals 3 and 4.

The second current driver circuit 20 has two switches SW₁ and SW₂ and weighted current-source transistors M₁ and M₂ corresponding to respective ones of these two switches. The current-source circuit 30 also two switches SW_{Ref1} and SW_{Ref2} and weighted current-source transistors M_{Ref1} and M_{Ref2} corresponding to respective ones of these two switches. In the second current driver circuit 20 and current-source circuit 30, both switches in both of these circuits are turned off in Interval 1 (the two bits of the video signal area “00”); switches SW₁ and SW_{Ref1} are turned on in Interval 2 (the two bits of the video signal area “01”); switches SW₂ and SW_{Ref2} are turned on in Interval 3 (the two bits of the video signal area “10”); and switches SW₁ and SW₂ and switches SW_{Ref1} and SW_{Ref2} are turned on in Interval 4 (the two bits of the video signal area “11”).

Since the luminance of the light-emitting element varies in proportion to the current that flows into the element, the luminance of the overall panel can be adjusted by varying the reference current I_{Ref} and the output current I_{OUT2} of the second current driver circuit 20.

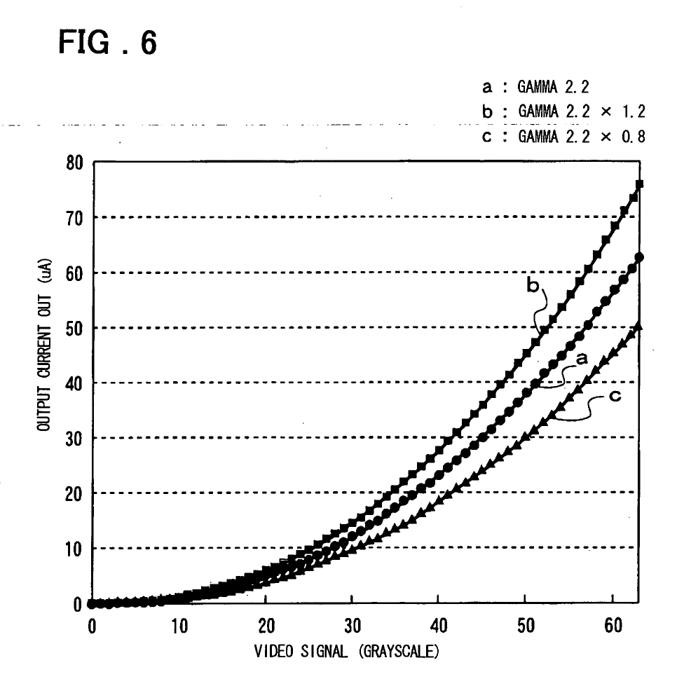

FIG. 6 illustrates an input/output characteristic (b in FIG. 6) in a case where the reference current I_{Ref} and output current I_{OUT2} of the second current driver circuit 20 have both been made 1.2 times the gamma value using the panel-luminance adjustment signal, and an input/output characteristic (c in FIG. 6) in a case where the reference current I_{Ref} and output current I_{OUT2} of the second current driver circuit 20 have both been made 0.8 times the gamma value using the panel-luminance adjustment signal.

The panel-luminance adjustment circuit 40 shown in FIG. 1 will be described next. The panel-luminance adjustment circuit 40 controls the source potentials of the PMOS and NMOS current sources in the current-source circuit 30 and second current driver circuit 20 by the panel-luminance adjustment signal that enters from the control terminal. In general, the saturation region of the transistors is used in a case where MOS transistors are employed as current sources. Drain current in the saturation region of a MOS transistor is expressed as follows:
I_{D}=β{V_{GS}−V_{T}}² (14)

Here I_{D} represents drain current, β is a gain coefficient, β=μC_{OX}W/L holds (where μ represents electron mobility, C_{OX} is the gate capacitance per a unit, W is the channel width and L is the channel length), V_{GS} represents the gate-to-source voltage and V_{T} is a threshold value.

When the gate-to-source voltage V_{GS} of the MOS transistor varies, the value of the current I_{D} that flows through the MOS transistors changes, as will be understood from the above equation.

In a case where the panel-luminance adjustment signal is given by a voltage value and can be supplied as is as a source voltage of the of the PMOS, NMOS current source, the luminance adjustment circuit 40 need not be provided. On the other hand, in a case where the panel-luminance adjustment signal is given by a digital signal or the like, a voltage conversion circuit that converts the digital panel-luminance adjustment signal to a voltage and outputs this voltage is required. For example, the luminance adjustment circuit 40 is constructed as shown in FIG. 9. The signal D3 in FIG. 9 is made the panel-luminance adjustment signal, and the output signal D_{CON} is made the control potential V_{CON1}. Information may be stored in a memory (not shown) beforehand and the information may be called and the potential V_{CON1} set.

According to this embodiment, current values supplied from the current sources are controlled collectively. This makes it possible to adjust the overall luminance of the panel while the gain characteristic is maintained.

This embodiment is strictly an example of the present invention and the combination of logic (truth tables) and current sources, etc., is not limited to that of the above embodiment. Although the above embodiment has been described with regard to an intake-type current driver circuit, an ejection-type current driver circuit can be implemented by interchanging the PMOS and NMOS transistors.

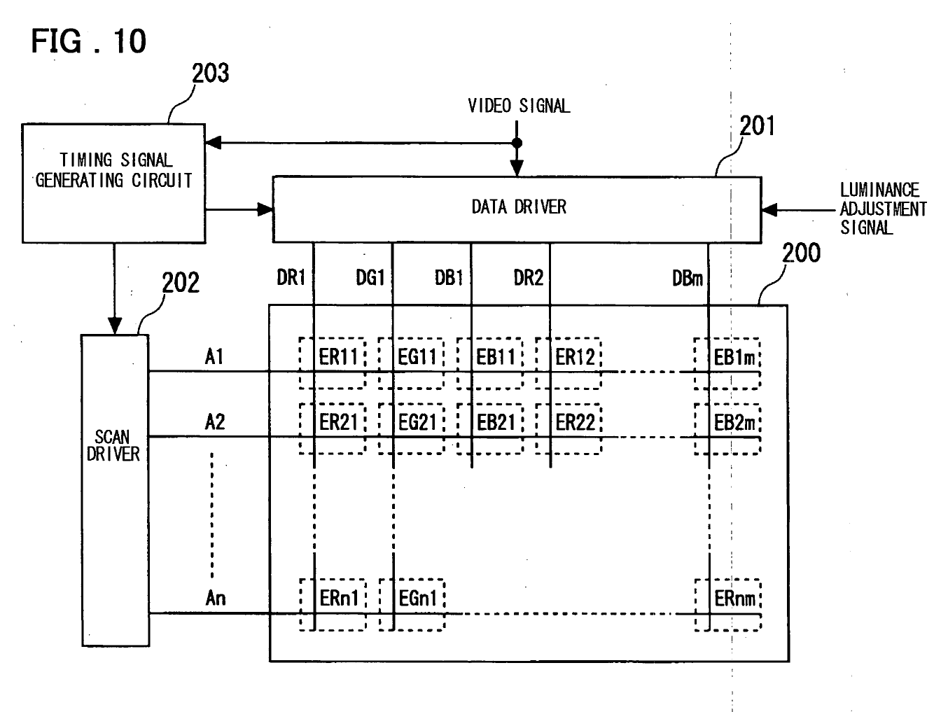

A display device according to the present invention will be described next. FIG. 10 is a diagram illustrating an implementation in which a display driver according to the present invention is applied to a display device of active-matrix drive type. The display panel 200 includes light-emitting units ER, EG and EB for emitting red, green and blue light, respectively, arrayed at the intersections of a plurality (n-number) of horizontal scan lines A1 to An of one screen and m-number of red drive data lines DR1 to DRm, m-number of green drive data lines DG1 to DGm and m-number of blue drive data lines DB1 to DBm disposed so as to intersect each of the scan lines. The light-emitting units comprise electroluminescent elements, by way of example.

In accordance with a video signal input thereto, a timing signal generating circuit 203 generates a timing signal, which indicates the application timing of scanning pulses applied sequentially to the scan lines A1 to An, and supplies the signal to a scan driver 202.

The scan driver 202 supplies the scan lines A1 to An of the display panel with scanning pulses sequentially in accordance with the timing signal supplied from the timing signal generating circuit 203.

The data driver 201 generates a current that corresponds to the logic level of the video signal and drives the drive data lines DR1 to DRm, DG1 to DGm and DB1 to DBm.

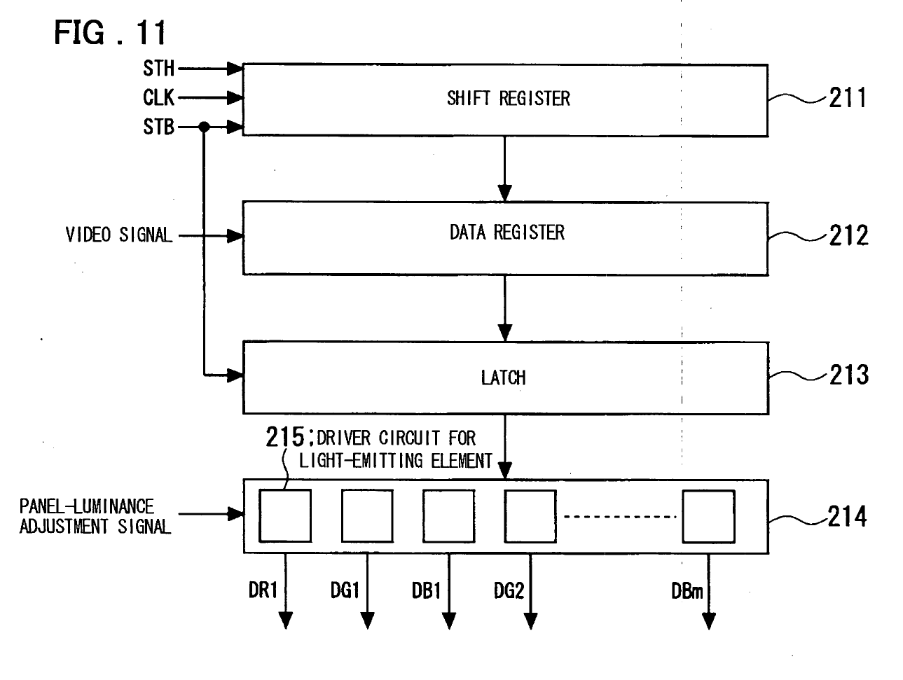

FIG. 11 is a block diagram illustrating the structure of the data driver 201 shown in FIG. 10. As shown in FIG. 11, the data driver 201 has a shift register 211, a data register 212, a latch circuit 213 and an output circuit 214. Signals input to the shift register 211, etc., are a synchronizing clock signal CLK, a start-pulse signal STH and a latch signal (strobe signal) STB that are supplied by the timing signal generating circuit 203. The video signal is input to the data register 212 and the panel-luminance adjustment signal is input to the output circuit 214. The output circuit 214 has a plurality (m×3) of driver circuits 215, which are for driving light-emitting elements, having output terminals connected to respective ones of m-number of red, green and blue drive data lines. Each driver circuit 215 is constituted by the light-emitting-element driver circuit embodying the present invention described above with reference to FIG. 1, etc.

The shift register 211 transfers the strobe signal STB, which is supplied by the start pulse STH constituting the start timing of the horizontal scanning interval, in accordance with the clock signal CLK and supplies the strobe signal successively to the data register 212.

The data register 212 samples the video signal in response to the strobe signal from the shift register 211 and transfers the video signal to the latch circuit 213.

The latch circuit 213 latches a plurality of video signals, which have been latched by the data register 212, all at once in response to the strobe signal STB and supplies the latched signals to the corresponding element driver circuits 215. The video signal supplied to the input terminal 1 in FIG. 1 is the signal latched by the latch circuit 213. The element driver circuit 215 also performs a gamma correction of gamma value 2.2, etc. Further, the element driver circuit 215 receives an input of the panel-luminance adjustment signal and performs an overall luminance adjustment of the display panel 200.

The light-emitting units ER, EG and EB for emitting red, green and blue light, respectively, are not identical with one another in terms of the relationship between the current that flows and luminance. Accordingly, in the present embodiment, the current supplied from each of the element driver circuits 215 is adjusted beforehand on a per-color basis, whereby panel luminance can be made uniform. Specifically, in this embodiment, the element driver circuits 215 are controlled individually depending upon the color of the light-emitting element, whereby the luminance of the panel is made uniform. Since each element driver circuit 215 performs a gamma correction internally of the driver circuit, it is unnecessary to provide a gamma correction circuit and chip area is reduced in a case where integration is performed. The circuit therefore is well suited for application to a semiconductor device.

The driver circuit for a light-emitting element illustrated in FIG. 1 can be construed as having the structure of a current-output-type digital-to-analog converter (DAC) circuit for performing a non-linear conversion such as a gamma correction. That is, a DA converter circuit to which a digital input signal is applied for converting the signal to an output current that conforms to the digital input signal and outputting the current comprises:
the first current driver circuit 10, which has a plurality of current sources the output current values whereof are decided based upon the reference current I_{Ref}, and switch circuits that on/off control current paths between the plurality of current sources and a current output terminal based upon a prescribed lower-order bit signal of the digital input signal;
the second current driver circuit 20 for outputting the second output current I_{OUT2} conforming to a prescribed higher-order bit signal of the digital input signal; and
the current-source circuit 30, which has the current source I_{REF} that generates the reference current (I_{REF}), for varying the reference current (I_{REF}) based upon the value of the digital input signal.

A current that is the result of combining the first and second output currents I_{OUT1} and I_{OUT2}, respectively, from the first and second current driver circuits is output as an output current I_{OUT}. An amount of change (quantization step) of the output current I_{OUT} that corresponds to a change in the unit amount (one LSB) of the digital input signal is varied in accordance with the value (interval) of the digital input signal. Of course, it may be so arranged that current that is output from the converter circuit is converted to a voltage and the driver circuit outputs a voltage conforming to the input voltage, whereby a voltage-drive-type display element such as a liquid crystal element is driven by a data signal that has been gamma-corrected in accordance with the grayscale. The input/output characteristic between the input signal and the output current can be set to a gamma characteristic having two inflection points (points where the polarity of curvature reverses), by way of example. Further, in the present invention, the input/output characteristic between the input signal and the output current can be set to a desired characteristic depending upon the number of current sources and set current values of the first and second current driver circuits and current-source circuit, and the way in which the input signal bits are partitioned.

Though the present invention has been described in accordance with the foregoing embodiments, the invention is not limited to these embodiments and it goes without saying that the invention covers various modifications and changes that would be obvious to those skilled in the art within the scope of the claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

1. A driver circuit comprising:
an input terminal for inputting a multiple-bit input signal, said input signal being partitioned into prescribed lower-order bits and higher-order bits that are situated above the lower-order bits;
an output terminal for outputting an output current;
a current-source circuit, having a current source that generates a reference current, for varying value of an output reference current based upon the higher-order bits of the input signal;
a first current generating circuit for generating and outputting a first output current, which corresponds to the lower-order bit signal of the input signal, based upon the reference current; and
a second current generating circuit for generating and outputting a second output current, which corresponds to the higher-order bit signal of the input signal;
wherein a current that is the result of combining the first and second output currents is output from said output terminal as the output current; and
a characteristic of the input signal, which is input to said input terminal, versus the output current that is output from said output terminal is made a predetermined input/output characteristic of a prescribed non-linearity.

2. The driver circuit according to claim 1, wherein said second current generating circuit includes a current source, different from the current source that generates the reference current, for generating and outputting the second output current.

3. The driver circuit according to claim 1, wherein a unit change in the input signal corresponds to the single-bit equivalent of the least significant bit of the input signal.

4. The driver circuit according to claim 1, wherein in an interval in which the higher-order bit signal of the input signal is not changed in value but is made a constant value and only the lower-order bit signal of the input signal is changed in value, the reference current and the second output current are each set to values that correspond to the constant value of the higher-order bit signal of the input signal.

5. The driver circuit according to claim 4, wherein the current value of the output current that corresponds to at least one end of said interval of the input signal is set to a current value that corresponds to an ideal value of the predetermined non-linear input/output characteristic, and a linear approximation of the non-linear input/output characteristic is performed on a per-interval basis.

6. A driver circuit for a light-emitting element in which emission of light is controlled in accordance with a supplied current, said driver circuit receiving a video signal that enters from an input terminal, generating a current that corresponds to the video signal and outputting the current from an output terminal, the video signal being partitioned into prescribed lower-order bits and higher-order bits situated above the lower-order bits, said driver circuit comprising:
a first current driver circuit, including a plurality of current sources, respective values of current thereof being decided based upon an applied reference current; and a plurality of switch circuits that on/off control current paths between the plurality of current sources and a current output terminal based upon the lower-order bit signal of the video signal, for generating and outputting a first output current that corresponds to the lower-order bit signal of the video signal;
a second current driver circuit, for generating and outputting a second output current, which corresponds to the higher-order bit signal of the video signal; and
a current-source circuit, including a current source that generates the reference current, for varying the output reference current based upon the higher-order bit signal of the video signal;
wherein a current that is the result of combining the first and second output currents from said first and second current driver circuits, respectively, is output from the output terminal as an output current; and
an amount of change in the output current that corresponds to a change in a unit quantity of the video signal is varied in accordance with the video signal.

7. The driver circuit according to claim 5, wherein said second current driver circuit includes a current source, different from the current source that generates the reference current, for generating and outputting the second output current.

8. The driver circuit according to claim 6, further comprising:
a first decoder for receiving and decoding the lower-order bit signal;
a second decoder for receiving and decoding the higher-order bit signal of the video signal; and
a third decoder for receiving and decoding the higher-order bit signal of the video signal;
wherein outputs of said first, second and third decoders are supplied to said first current driver circuit, said second current driver circuit and said current-source circuit, respectively.

9. The driver circuit according to claim 6, wherein the unit quantity of the video signal is a single-bit equivalent of the least significant bit of the video signal.

10. The driver circuit according to claim 6, wherein in an interval in which the higher-order bit signal of the video signal is not changed in value but is made a constant value and only the lower-order bit signal of the video signal is changed in value, the reference current and the second output current are each set to values that correspond to the constant value of the higher-order bit signal of the video signal.

11. The driver circuit according to claim 10, wherein the current value of the output current that corresponds to at least one end of said interval of the video signal is set to a current value that corresponds to a logic value of the predetermined non-linear input/output characteristic, and a linear approximation of the non-linear input/output characteristic is performed on a per-interval basis.

12. The driver circuit according to claim 6, further comprising a luminance adjustment circuit for varying a control voltage, which is output thereby, based upon a control signal that enters from a control terminal;
wherein said current-source circuit receives the control voltage output from said luminance adjustment circuit and varies the current value of the output reference current based upon the control voltage.

13. The driver circuit according to claim 12, wherein said second current driver circuit varies the current value of the second output current based upon the control voltage.

14. The driver circuit according to claim 6, further comprising a decoder for decoding the lower-order bit signal of the video signal; wherein said first current driver circuit includes:
a multiple-output current mirror circuit, having an input terminal to which the reference current is input, for outputting currents that mirror the reference current from respective ones of a plurality of output terminals; and
a plurality of switching elements, each of which has a control terminal that receives the lower-order bit signal of the video signal or a signal obtained by decoding the lower-order bit signal of the video signal by said decoder, a first end connected to a respective output terminal of the plurality of output terminals of said current mirror circuit, and a second end connected to the current output terminal.

15. The driver circuit according to claim 8, wherein said current-source circuit includes:
a plurality of current sources having first ends connected in common to a first potential; and
a plurality of switching elements, which have first ends connected to output terminals of respective ones of said plurality of current sources and second ends connected in common to a reference current output terminal that outputs the reference current, for being on/off controlled based upon a signal that is output from said third decoder.

16. The driver circuit according to claim 8, wherein said current-source circuit includes:
one or a plurality of current sources having a first end connected to a first potential and an output terminal connected to a current output terminal that outputs the reference current; and
a voltage selection circuit for supplying a bias voltage to said one or plurality of current sources based upon result of decoding by said third decoder;
said current source varying the output current from the output terminal of said current source in accordance with the bias voltage.

17. The driver circuit according to claim 16, wherein said voltage selection circuit in said current-source circuit includes:
a resistor circuit, which has a plurality of resistors connected serially between a high reference potential and a low reference potential, for outputting corresponding voltages from a predetermined plurality of taps from among the high reference potential, low reference potential and nodes between mutually adjacent ones of said resistors; and
a plurality of switching elements, connected between the plurality of taps of said resistor circuit and an output terminal that outputs the bias voltage, for being on/off controlled by an output signal from said third decoder.

18. The driver circuit according to claim 15, further comprising a luminance adjustment circuit for generating a variable control voltage based upon a control signal applied thereto;
wherein the control voltage is supplied as the first potential of said current-source circuit.

19. The driver circuit according to claim 8, wherein further said second current driver circuit includes:
a plurality of current sources having first ends connected in common to a second potential; and
a first group of switching elements, having first ends connected to output terminals of respective ones of said plurality of current sources and second ends connected in common to a current output terminal, for being on/off controlled based upon a signal from said second decoder received at a control terminal thereof.

20. The driver circuit according to claim 8, wherein said second current driver circuit includes:
one or a plurality of current sources, each having a first end connected to a second potential and an output terminal connected to a current output terminal that outputs the reference current; and
a voltage selection circuit for supplying a bias voltage to said one or plurality of current sources based upon result of decoding by said second decoder;
said current source varying the output current from the output terminal of said current source in accordance with the bias voltage.

21. The driver circuit according to claim 20, wherein said voltage selection circuit includes:
a resistor circuit, having a plurality of resistors serially connected between a high reference potential and a low reference potential, for outputting corresponding voltages from a predetermined plurality of taps from among the high reference potential, low reference potential and nodes between mutually adjacent ones of said resistors; and
a plurality of switching elements, connected between the respective plurality of taps of said resistor circuit and an output terminal that outputs the bias voltage, for being on/off controlled by an output signal from said second decoder.

22. The driver circuit according to claim 19, further comprising a luminance adjustment circuit for generating a variable control voltage, which is output thereby, based upon a control signal applied thereto from a control signal input terminal;
wherein the control voltage that is output from said luminance adjustment circuit is supplied as the second potential of said second current driver circuit.

23. The driver circuit according to claim 20, further comprising a luminance adjustment circuit for generating a variable control voltage, which is output thereby, based upon a control signal applied thereto from a control signal input terminal;
wherein the control voltage that is output from said luminance adjustment circuit is supplied as the second potential of said second current driver circuit.

24. The driver circuit according to claim 12, wherein the non-linear input/output characteristic is made a prescribed gamma-value characteristic, and the output current produced is one obtained by correcting the video signal in accordance with the predetermined gamma value.

25. A display device having the driver circuit for a light-emitting element set forth in claim 6 as a driver circuit for driving a display element of a display-element panel, wherein it is unnecessary to provide a gamma correction circuit in front of said driver circuit for driving the display element.

26. A display device comprising:
a display panel having a plurality of scan lines arrayed along the horizontal direction, a plurality of data lines arrayed along the vertical direction and a plurality of display elements provided at intersections of said scan lines and data lines;
a scan driver for driving the scan lines; and
a data driver, receiving a video signal, for driving the data lines;
wherein said data driver has the driver circuits for light-emitting elements set forth in claim 6 as driver circuits for driving the data lines.

27. The display device according to claim 26, wherein said drivers for light-emitting elements, which are provided in correspondence with colors of the light-emitting elements, are controlled individually on a per-color basis to uniformalize panel luminance.

28. A semiconductor device having the driver circuit set forth in claim 1.

29. A current-output-type digital-to-analog converter, receiving a digital signal as an input for converting the digital signal to an output current and outputting the output current, the input digital signal being partitioned into higher-order bits and lower-order bits, said converter comprising:
a first current driver circuit, having a plurality of current sources in which values of current to be output are decided based upon an applied reference current, and a plurality of switch circuits that on/off control current paths between the plurality of current sources and a current output terminal based upon the lower-order bit signal of the digital signal, for generating and outputting a first output current that conforms to the lower-order bit signal;
a second current driver circuit, receiving the higher-order bit signal of the digital signal, for generating and outputting a second output current that conforms to the higher-order bit signal; and
a reference current-source, having a current source that outputs the reference current, for varying the reference current based upon the value of the higher-order bit signal of the digital signal;
wherein a current that is the result of combining the first and second output currents from said first and second current driver circuits, respectively, is output as an output current; and
an amount of change in the output current that corresponds to a change in a unit quantity of the digital signal is varied in accordance with the value of the input signal.

30. The current-output-type digital-to-analog converter according to claim 29, wherein said second current driver circuit includes a current source, different from the current source that generates the reference current, for generating and outputting the second output current.
